(19) United States
(12) Patent Application Publication
(10) Pub. No.: US 2013/0236713 A1
(43) Pub. Date: Sep. 12, 2013

(54) TRANSPARENT FLEXIBLE FILM AND METHOD FOR MANUFACTURING THEREOF

(71) Applicants: Byoung Cheul Park, Chungcheongnam-do (KR); Chul Hwangbo, Gyeonggi-do (KR); Dae Sig Ahn, Seoul (KR)

(72) Inventors: Byoung Cheul Park, Chungcheongnam-do (KR); Chul Hwangbo, Gyeonggi-do (KR); Dae Sig Ahn, Seoul (KR)

(73) Assignee: KOLONGLOTECH, INC., Gwacheon-si, Gyeonggi-do (KR)

(21) Appl. No.: 13/885,717

(22) PCT Filed: Nov. 18, 2010
(86) PCT No.: PCT/KR2010/008146

§ 371 Date: May 16, 2013

(30) Foreign Application Priority Data
Nov. 18, 2010 (KR) 10-2010-0114833

(51) Int. Cl. H01L 31/045; H01L 31/18

(52) U.S. Cl. CPC H01L 31/045; H01L 31/18
USPC 428/216; 427/108; 428/335

(57) ABSTRACT

A transparent flexible film and a method of manufacturing thereof. An inorganic layer is formed by coating ionized metal compound on a surface of a transparent substrate film and naturally cured so as to react with moisture in the air. Accordingly, the transparent flexible film for solar cell has low permeability rate of water and oxygen.

### CROSS REFERENCE TO RELATED APPLICATIONS AND CLAIM OF PRIORITY

This patent application is a National Phase application under 35 U.S.C. §371 of International Application No. PCT/KR2010/008146, filed Nov. 18, 2010, which claims priority to Korean Patent Application No. 10-2010-0114833 filed Nov. 18, 2010, entire contents of which are incorporated herein by reference.

### BACKGROUND

1. Technical Field

The present invention relates to a transparent flexible film for solar cell and a method of manufacturing thereof.

2. Description of the Related Art

The conventional solar cell modules are made of glass and have the advantageous of transparent of solid and barrier properties, but are problematic in that they are fragile, and lack flexibility, there is thickness limitation and they have a high weight per unit volume. As an alternative that overcomes the above-mentioned deficiencies of the conventional glass substrate, flexible plastics substrates have been proposed.

In a recent year, the development of solar cell modules has led to gas-barrier type film with a preference for lightweight and excellent gas-barrier protective function as well as freely bent and fold to be applied to flexible solar cells. Accordingly, transparent plastics or resin films as substrates have been studying instead of glass substrates that are fragile and have the limitation used in large areas.

The demands for these excellent mechanical flexibility and gas-barrier properties used in various display apparatus such as LCD (Liquid Crystal Display), OLED (Organic Lighting Emitting Diodes (OLED), Electric Paper Display (EPD), and the like, is on the rise.

Since gas-barrier property of plastic or resin films inferior to that of glass substrates, vapor or oxygen can be permeated through substrates, thereby deteriorating life and quality of solar cell modules. Since such problems relating to the gas permeability of the plastic substrate are difficult to overcome by improving the performance of the plastic substrate itself, methods of coating the surface of the plastic substrate with thin film capable of preventing the penetration of gas such as oxygen and water vapor, have been used.

Recently, transparent gas barrier films formed of inorganic material silicon oxides, aluminum oxides by vacuum deposition method, sputtering, ion planting method, chemical vapor deposition and the like are drawing great attention as barrier materials with respect to oxygen or water vapor. However, since these transparent gas barrier films are formed by depositing inorganic oxides on substrates that are made of biaxial stretch polyester with good transparency and stiffness, resin layer may soften. In other words, deposition is carried out at high temperature to form a thin film, and a resin layer may soften due to heat load, and thus a heat-resistant plastic such as polyethylene terephthalate, polybutylene terephthalate, polyethylene terephthalate, polyethylene naphthalate, or polyimide must be exclusively employed. Also, there is disadvantageous in that when a rein of low Young's modulus is employed, gas-barrier properties of a produced film may deteriorate, since the tensile strength of the resin decreases during deposition and the deposited film is prone to crack.

Since deposition must be carried out in a vacuum apparatus, it is also disadvantageous in that operation is cumbersome and an expensive apparatus is required. Therefore, there has been demand for a process for producing a gas barrier-film more simply and conveniently.

### SUMMARY

The inventors of the present invention completed the present invention resulting from efforts to develop an inorganic layer that is formed by coating ionized metal compound on a surface of a transparent substrate film and naturally cured so as to react with moisture in the air.

Accordingly, an object of the present invention is to provide a transparent flexible film having low permeability rate of water and oxygen by forming an inorganic layer by coating ionized metal compound on a surface of a transparent substrate film and naturally cured so as to react with moisture in the air and a method of making thereof.

Another object of the present invention is to provide a transparent flexible film that can be produced at a low cost without using high cost of deposition apparatus and a method thereof.

A further object of the present invention is to provide a transparent flexible film capable of improving life of a solar cell module due to excellent mechanical flexibility and low permeability rate of water and oxygen.

The objects of the invention are not limited to the above-mentioned objects, and other unmentioned objects will be clearly interpreted by those skilled in the art from the following description.

Embodiments of the present invention provide a method for manufacturing a transparent flexible film including (a) forming a first inorganic layer by coating ionized metal compound on a surface of a transparent substrate film and naturally cured so as to react with moisture in the air and (b) coating an organic layer on the first inorganic layer.

Pursuant to some embodiments of the present invention, after the (b) step, further including (c) forming a second inorganic layer by coating ionized metal compound on a surface of the organic layer and naturally cured so as to react with moisture in the air.

Pursuant to some embodiments of the present invention, in the (a) step, wherein the inorganic layer is represented by the following formula:

M(OR)ₙ+nH₂O→M(OH)_{X}+nROH [Formula]

wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and wherein in case that R represents an alkyl group, the alkyl group can be replaced by fluorine instead of hydrogen.

Pursuant to some embodiments of the present invention, the first inorganic layer in the (a) step and the second inorganic layer in the (c) step are represented by the following formula:

M(OR)ₙ+nH₂O→M(OH)_{X}+nROH [Formula]

wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and wherein in case that R represents an alkyl group, the alkyl group can be replaced by fluorine instead of hydrogen.

Pursuant to some embodiments of the present invention, the transparent substrate film is made of polymer or plastic material.

Pursuant to some embodiments of the present invention, the polymer or the plastic material is at least one selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, and polyvinyl chlorides.

Pursuant to some embodiments of the present invention, organic material used for coating the organic layer is at least one selected from the group consisting of benzocyclobutene (BCB), acrylic resin, epoxy resin, polyvinyl phenol (PVP), and polyvinyl alcohol (PVA).

Pursuant to some embodiments of the present invention, the first inorganic layer of the (a) step has a thickness of 0.5 μm to 30 μm.

Pursuant to some embodiments of the present invention, the first inorganic layer of the (a) step and the second inorganic layer of the (c) step have a thickness of 0.5 μm to 30 μm.

Pursuant to some embodiments of the present invention, the (a), (b), and (c) steps are performed on one side or both sides of the transparent substrate film at a one-time process or repeatedly.

Embodiments of the present invention provide transparent flexible film including a transparent substrate film, a first inorganic layer formed on the transparent substrate film and an organic layer formed on the first inorganic layer. In this case, the first inorganic layer is M(OH)ₓ formed by ionized metal compound reacting with moisture in the air to be naturally cured as the following formula:

M(OR)ₙ+nH₂O→M(OH)_{X}+nROH [Formula]

wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and in case that R represents an alkyl group, the alkyl group can be replaced by fluorine instead of hydrogen.

Pursuant to some embodiments of the present invention, a second inorganic layer on the organic layer is further included. In this case, the second inorganic layer is M(OH)ₓ formed by ionized metal compound reacting with moisture in the air to be naturally cured.

Pursuant to some embodiments of the present invention, the transparent substrate film is made of polymer or plastic material.

Pursuant to some embodiments of the present invention, the polymer or the plastic material is at least one selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, and polyvinyl chlorides.

Pursuant to some embodiments of the present invention, organic material used for coating the organic layer is at least one selected from the group consisting of benzocyclobutene (BCB), acrylic resin, epoxy resin, polyvinyl phenol (PVP), and polyvinyl alcohol (PVA).

Pursuant to some embodiments of the present invention, the first inorganic layer has a thickness of 0.5 μm to 30 μm.

Pursuant to some embodiments of the present invention, the first inorganic layer and the second inorganic layer have a thickness of 0.5 μm to 30 μm.

Pursuant to some embodiments of the present invention, the first inorganic layer, the organic layer, and the second inorganic layer are sequentially stacked on one side of the transparent substrate film.

Pursuant to some embodiments of the present invention, the first inorganic layer, the organic layer, and the second inorganic layer are repeatedly stacked on one side of the transparent substrate film.

Pursuant to some embodiments of the present invention, the first inorganic layer, the organic layer, and the second inorganic layer are sequentially stacked on both sides of the transparent substrate film.

Pursuant to some embodiments of the present invention, the first inorganic layer, the organic layer, and the second inorganic layer are repeatedly stacked on both sides of the transparent substrate film.

The present invention has the following effects.

First, an inorganic layer with excellent gas barrier property is formed by coating ionized metal compound on a surface of a transparent substrate film and naturally cured so as to react with moisture in the air. As a result, a transparent flexible film having low permeability rate of water and oxygen can be formed.

In addition, since inorganic layer is formed using spray printing or spray coating and naturally cured so as to react with moisture in the air, so that the high cost of deposition apparatus is not required, thereby lowering the process cost and simplifying process.

Further, a transparent flexible film according to the present invention can be applied not to a solar cell module, but to Liquid Crystal Display (LCD), Organic Lighting Emitting Diodes (OLED), and Electric Paper Display (EPD).

Moreover, a transparent flexible film according to the present invention has low permeability rate of water and oxygen as well as mechanical flexibility, thereby improving life of a solar cell module.

### BRIEF DESCRIPTION OF DRAWINGS

FIG. 1 is a cross-sectional construction view of a transparent flexible film according to an embodiment of the present invention.

FIG. 2 is a cross-sectional construction view of a transparent flexible film according to another embodiment of the present invention.

FIG. 3 is a cross-sectional construction view of a transparent flexible film according to still another embodiment of the present invention.

FIG. 4 is a cross-sectional construction view of a transparent flexible film according to yet another embodiment of the present invention.

### DETAILED DESCRIPTION

The terminology which is used in common will be used for the purpose of description and not of limitation. Furthermore, terms and words used by the applicant may be used for special cases. In this case, the meaning of terms or words must be understood with due regard to the meaning expressed in the specification rather than taking into account only the basic meaning of the terms and words.

Hereinafter, the technical construction of the present invention will be described in detail with reference to preferred embodiments illustrated in the attached drawings.

The present invention may, however, be embodied in different forms and should not be construed as limited to the embodiments set forth herein. The same reference numeral is used to refer to like elements throughout.

As used herein, the terms “about”, “substantially”, etc. are intended to allow some leeway in mathematical exactness to account for tolerances that are acceptable in the trade and to prevent any unconscientious violator from unduly taking advantage of the disclosure in which exact or absolute numerical values are given so as to help understand the invention.

A transparent flexible film according to the present invention includes (a) forming a first inorganic layer by coating ionized metal compound on a surface of a transparent substrate film and naturally cured so as to react with moisture in the air and (b) coating an organic layer on the first inorganic layer. In addition, after the (b) step, (c) forming a second inorganic layer by coating ionized metal compound on a surface of the organic layer and naturally cured so as to react with moisture in the air is further included.

In the (a) step, the first inorganic layer is formed on the transparent substrate film. The first inorganic layer is a barrier layer for preventing gas such as oxygen or vapor.

Polymer or plastic can be used as the transparent substrate film. Suitable polymer of the present invention is, but not limited to, polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, and polyvinyl chlorides.

A first inorganic layer is formed by coating ionized metal compound on a surface of the transparent substrate film and naturally cured so as to react with moisture in the air. At this time, the first inorganic layer is formed is represented by the following formula:

M(OR)ₙ+nH₂O→M(OH)_{X}+nROH [Formula]

wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and in case that R represents an alkyl group, the alkyl group can be replaced by fluorine instead of hydrogen.

Coating solvent was made by melting metal compound represented by M(OR)ₙ and then adding catalyst. At a predetermined temperature and duration of time, the coating solvent was stirred to form ionic metal compound. Generally, various kinds of materials, such as tetraethoxysilane (Si(O.C₂H₅)₄), can be used.

The most common way can be adopted to coat ionic metal compound on a surface of the transparent substrate film. Typical examples are dipping, roll court, gravure court, reverse court, air knife court, comma court, die court, screen printing, spray court, and gravure offset etc. By employing these pottery ceramic methods, one side or both sides of the transparent substrate film can be coated.

The ionized metal compound coated on the surface of the transparent substrate film is naturally cured to react with moisture in the air. Resulting from natural curing, the nROH material (material containing alcohol) becomes volatilized, and a first inorganic layer is formed on the transparent substrate film.

While forming the first inorganic layer, drying process such as high-frequency irradiation, infrared irradiation, UV irradiation are not used. As a result, the inorganic layer can be formed at a low cost and via simplification process owing to low cost. Preferably, the first inorganic layer has a thickness of 0.5 μm to 30 μm.

In the (b) step, an organic layer is formed on the first inorganic layer. In order to planarize and stabilize the surface of the transparent substrate film including the first inorganic layer, the organic layer is formed. In other words, the coated organic layer performs function not to fill pinhole and crack, but to improve smoothness (Ra>2 nm) and complete compactness composition.

Any of organic materials can be used as the organic layer. The most suitable organic material according to the present invention is, but not limited to, benzocyclobutene (BCB), acrylic resin, epoxy resin, polyvinyl phenol (PVP), and polyvinyl alcohol (PVA).

The most common way can be adopted to coat the organic layer. Typical examples are dipping, roll court, gravure court, reverse court, air knife court, comma court, die court, screen printing, spray court, and gravure offset etc.

Continuously, a second inorganic layer is formed on the organic layer in the (c) step. That is, the second inorganic layer is formed by coating the ionized metal compound on the surface of the organic layer and naturally cured so as to react with moisture in the air. The second inorganic layer is a second barrier layer for preventing gas such as oxygen or vapor. The second inorganic layer prevents gas together with the first inorganic layer to have barrier property. The second inorganic layer is represented by the following formula the same as the method of manufacturing the first inorganic layer:

M(OR)ₙ+nH₂O→M(OH)_{X}+nROH [Formula]

wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and in case that R represents an alkyl group, the alkyl group can be replaced by fluorine instead of hydrogen.

Coating solvent was made by melting metal compound represented by M(OR)ₙ and then adding catalyst. At a predetermined temperature and duration of time, the coating solvent was stirred to form ionic metal compound. Various kinds of materials can be used as metal compound, and, for example, tetraethoxysilane (Si(O.C₂H₅)₄) can be used.

Preferably, the second inorganic layer has a thickness of 0.5 μm to 30 μm.

The transparent flexible film manufactured by the above-mentioned processes has excellent protective ability with respect to oxygen or vapor as well as transparency and mechanical flexibility, so that it can be applied to solar cell modules. A transparent flexible film in accordance with an embodiment of the present invention is formed on a SUS substrate. CIGS layer is stacked on the transparent flexible film. Then, electrodes are formed to create unit cell of a solar cell. A solar cell module employing the transparent flexible film according to the present invention has a low permeation rate of water and oxygen and dramatic mechanical flexibility, thereby improving life thereof.

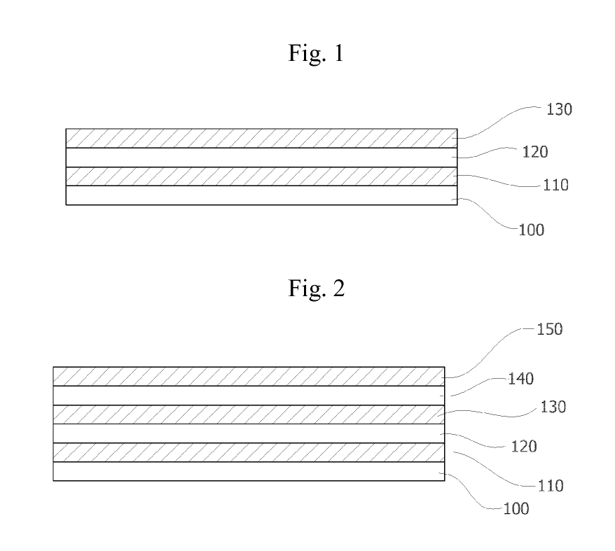

FIGS. 1 to 4 are cross-section construction views of a transparent flexible film according to embodiments of the present invention.

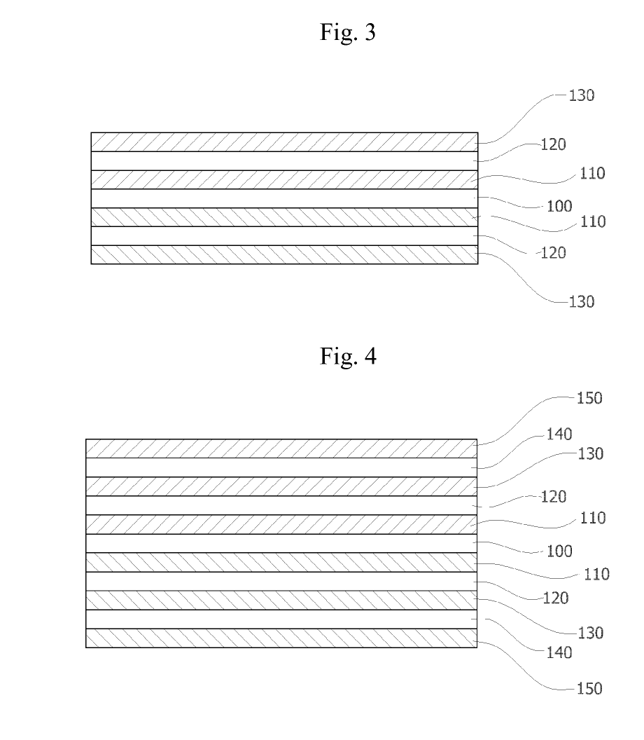

As shown in FIG. 1, the first inorganic layer 110, the organic layer 120, and the second inorganic layer 130 can be sequentially stacked on one side of transparent substrate film 100. As shown in FIG. 2, the first inorganic layer 110, the organic layer 120, and the second inorganic layer 130 can be repeatedly stacked on one side of transparent substrate film 100. That is, an additional organic layer 140 and an additional inorganic layer 150 can be further stacked as shown in FIG. 2. In other words, the first inorganic layer 110, the organic layer 120, and the second inorganic layer 130 can be stacked on the transparent substrate film 100 in one layer or multi-layered layer repeatedly. Additionally, they can be stacked on one side of the transparent substrate film as shown in FIGS. 1 and 2, or both sides of the transparent substrate film as shown in FIGS. 3 and 4, which are considered to be within the scope of the present invention.

The present invention will be explained later in detail. However, it is to be understood that the scope of the invention is not limited to the disclosed embodiments.

### EXAMPLES

### Example 1

In order to form the first inorganic layer, tetraethoxysilane (Si(O.C₂H₅)₄) as initiator was melted with IPA (Icosapentaenoic acid), and then the resulting mixture was stirred by adding catalyst at 25° C. for 2 hours to thereby form ionic metal compound. After carrying out the ionic metal compound on one side of the transparent substrate film (PET) having a thickness of 100 μm by spin court manner, a transition process was performed through natural curing at a room temperature for 6 hours, so that the first inorganic layer Si(OH)₄ was formed. We found out that the thickness of the inorganic layer is 3 μm by alpha stepper. The surface of the first inorganic layer was coated with a coating agent consist of benzocyclobutene (BCB) by carrying out spin court and then was dried at 120° C. for 2 hours to thereby form an organic layer. After drying, the organic layer had a thickness of 100 μm by alpha stepper. A second inorganic layer reacting with the same condition as the manufacturing process of the first inorganic layer was formed on the surface of the organic layer, thereby forming a multi-layered transparent flexible film.

With respect to the multi-layered transparent flexible film fabricated in the example 1, main properties of substrates for display devices being oxygen transmission rate, vapor transmission rate, deformation temperature, optical transmission rate, pencil hardness, and average roughness were measured by the following methods, where the results are shown in Table 1 as follows.

Measurement of Oxygen Transmission Rate

The oxygen transmission rate values of the transparent flexible film were measured by using an oxygen transmission rate apparatus (Oxtran 2/20 MB, Mocon) at room temperature and 0% relative humidity. The detection limit was 0.01 g/m 2·day, and if less than the detection limit, it showed 0.01 g/m 2·day.

Measurement of Vapor Transmission Rate

The vapor transmission rate values of the transparent flexible film was measured by using a vapor transmission rate apparatus (Permatran-w-3/33, ASTM F 1249) at room temperature and 100% relative humidity for 1 hour. The detection limit was 0.01 g/m 2·day, and if less than the detection limit, it showed 0.01 g/m 2·day.

Measurement of Deformation Temperature

The deformation temperature of the transparent flexible film was measured by a point of inflection in which length variation was dramatically changed at 5 gf using a Thermal Mechanical Analyzer (TMA).

Measurement of Optical Transmission Rate

The optical transmission rate of the transparent flexible film was measured by using UV-spectrometer manufactured by Varian company based on ASTM D1003 in visible rays from 380 μm to 780 μm

Measurement of Pencil Hardness

The pencil hardness of the transparent flexible film was measure by scratching at two times and more with pencils having different hardness under 200 g loads. By observing with naked eye, the pencil hardness in which there is no scratch was considered to that of a surface of the transparent flexible film.

Measurement of Average Roughness and Maximum Roughness

The average roughness (Ra) and maximum roughness (Rmax) of the transparent flexible film was measure by interatomic force microscope in range of 20 μm.

TABLE 1

| | Oxygen | Vapor | | Optical | | |
|---|---|---|---|---|---|---|
| | transmission | transmission | Deformation | Transmission | Pencil | Average |
| | Rate | Rate | Temperature | Rate | Hardness | Roughness |
| Unit | cc/m2/day | g/m2/day | ° C. | % | H | nm |
| Example 1 | <0.01 | <0.01 | >200 | >92 | >4 | 1.5 |

Although the present invention has been described herein with reference to the foregoing embodiments and the accompanying drawings, the scope of the present invention is defined by the claims that follow. Accordingly, those skilled in the art will appreciate that various substitutions, modifications and changes are possible, without departing from the spirit of the present invention as disclosed in the accompanying claims. It is to be understood that such substitutions, modifications and changes are within the scope of the present invention.

1. A method for manufacturing a transparent flexible film comprising:
forming a first inorganic layer by coating ionized metal compound on a surface of a transparent substrate film and naturally cured at room temperature so as to react with moisture in the air; and
coating an organic layer on the first inorganic layer;
wherein the first inorganic layer has a thickness of 1 μm to 30 μm and is represented by the following formula:
M(OR)n+nH2O→M(OH)X+nROH [Formula]
wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and
wherein in case that R represents the alkyl group, a hydrogen atom of the alkyl group is optionally replaced by fluorine.

2. The method according to claim 1, further comprising forming a second inorganic layer by coating ionized metal compound on a surface of the organic layer and naturally cured at room temperature so as to react with moisture in the air,
wherein the second inorganic layer has a thickness of 1 μm to 30 μm and is represented by the following formula:
M(OR)n+nH2O→M(OH)x+nROH
wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and
wherein in case that R represents alkyl group, a hydrogen atom of the alkyl group is optionally replaced by fluorine.

3. (canceled)

4. (canceled)

5. The method according to claim 1, wherein the transparent substrate film is made of polymer or plastic material.

6. The method according to claim 5, wherein the polymer or the plastic material is selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, polyvinyl chlorides, and a combination thereof.

7. The method according to claim 1, wherein organic material used for coating the organic layer is at least one selected from the group consisting of benzocyclobutene (BCB), acrylic resin, epoxy resin, polyvinyl phenol (PVP), polyvinyl alcohol (PVA), and a combination thereof.

8. (canceled)

9. (canceled)

10. The method according to claim 2, wherein said forming the first inorganic layer, said coating the organic layer and said forming the second inorganic layer are performed on one side or both sides of the transparent substrate film at a one-time process or repeatedly.

11. A transparent flexible film comprising:
a transparent substrate film;
a first inorganic layer formed on the transparent substrate film; and
an organic layer formed on the first inorganic layer, the organic layer formed of one selected from the group consisting of benzocyclobutene (BCB), polyvinyl phenol (PVP), polyvinyl alcohol (PVA), and a combination thereof,
wherein the first inorganic layer has a thickness of 1 μm to 30 μm and is M(OH)ₓ formed by ionized metal compound reacting with moisture in the air to be naturally cured as the following formula:
M(OR)ₙ+nH₂O→M(OH)_{X}+nROH [Formula]
wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and
wherein in case that R represents an alkyl group, a hydrogen atom of the alkyl group is optionally replaced by fluorine.

12. The transparent flexible film according to claim 11, further comprising a second inorganic layer on the organic layer,
wherein the second inorganic layer has a thickness of 1 μm to 30 μm and is M(OH)ₓ formed by coating ionized metal compound on a surface of the organic layer and naturally cured at room temperature so as to react with moisture in the air as the following formula:
M(OR)ₙ+nH₂O→M(OH)_{X}+nROH [Formula]
wherein M is any one selected from the group consisting of Si, B, Li, Na, K, Mg, Ca, Ti, Al, Ba, Zn, Ga, Ge, Bi, and Fe, and R represents an aryl group having 6 to 20 carbon atoms or an alkyl group having 1 to 20 carbon atoms, and
wherein in case that R represents an alkyl group, a hydrogen atom of the alkyl group is optionally replaced by fluorine.

13. The transparent flexible film according to claim 11, wherein the transparent substrate film is made of polymer or plastic material.

14. The transparent flexible film according to claim 13, wherein the polymer or the plastic material is selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, polyvinyl chlorides, and a combination thereof.

15. (canceled)

16. (canceled)

17. (canceled)

18. The transparent flexible film according to claim 12, wherein the first inorganic layer, the organic layer, and the second inorganic layer are sequentially stacked on one side of the transparent substrate film.

19. The transparent flexible film according to claim 12, wherein the first inorganic layer, the organic layer, and the second inorganic layer are repeatedly stacked on one side of the transparent substrate film.

20. The transparent flexible film according to claim 12, wherein the first inorganic layer, the organic layer, and the second inorganic layer are sequentially stacked on both sides of the transparent substrate film.

21. The transparent flexible film according to claim 12, wherein the first inorganic layer, the organic layer, and the second inorganic layer are repeatedly stacked on both sides of the transparent substrate film.

22. The method according to claim 2, wherein the transparent substrate film is made of polymer or plastic material.

23. The method according to claim 22, wherein the polymer or the plastic material is selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamide-imide, polyimide, aromatic polyimide, polyetherimide, acrylonitrile butadiene styrene, ethylene tetrafluoroethylene, polyvinyl chlorides, and a combination thereof.

24. The method according to claim 2, wherein organic material used for coating the organic layer is selected from the group consisting of benzocyclobutene (BCB), acrylic resin, epoxy resin, polyvinyl phenol (PVP), polyvinyl alcohol (PVA), and a combination thereof.

25. The method according to claim 1, wherein said forming the first inorganic layer and said coating the organic layer are performed on one side or both sides of the transparent substrate film at a one-time process or repeatedly.

26. The transparent flexible film according to claim 12, wherein the transparent substrate film is made of polymer or plastic material.

27. The transparent flexible film according to claim 26, wherein the polymer or the plastic material is selected from the group consisting of polyestersulfone, polyethylene, polycarbonate, polystyrene, polyethylene terephthalate, polyethylene naphthalate, polybutylene terephthalate, polyphenylene sulfide, polypropylene, aramid, polyamideimide, polyimide, aromatic polyimide, polyetherimide, acrylonitrile butadienestyrene, ethylene tetrafluoroethylene, polyvinyle chlorides, and a combination thereof.
